(19) United States
(12) Patent Application Publication
(10) Pub. No.: US 2011/0061814 A1
(43) Pub. Date: Mar. 17, 2011

(54) MICROWAVE INTRODUCING MECHANISM, MICROWAVE PLASMA SOURCE AND MICROWAVE PLASMA PROCESSING APPARATUS

(75) Inventor: Taro Ikeda, Yamanashi (JP)

(73) Assignee: TOKYO ELECTRON LIMITED, Tokyo (JP)

(21) Appl. No.: 12/922,243

(22) PCT Filed: Mar. 5, 2009
(86) PCT No.: PCT/JP2009/054158

§ 371 Date: Nov. 29, 2010

(30) Foreign Application Priority Data
Mar. 14, 2008 (JP) 2008-066277

(51) Int. Cl. H01L 21/3065; H01J 37/32

(52) U.S. Cl. 156/345.41; 333/99 PL; 315/111.21

(57) ABSTRACT

A microwave introducing mechanism 43 includes a cylindrical container 50; an inner conductor 52, coaxially provided in the container 50, a microwave transmission path being defined between the container 50 and the inner conductor 52; a tuner 44 for adjusting an impedance of the microwave transmission path 53; and an antenna section 45 including an antenna 51 for radiating to the chamber a microwave transmitted through the microwave transmission path 53. The tuner 44 includes a pair of slugs 58 made of a dielectric material and movable along the inner conductor 52; an actuator 59 for moving the slugs 58; and a controller 60. The controller 60 controls both the slugs 58 to move together in a range of a ½ wavelength of the microwave and one of the slugs 58 to move in a range of a ¼ wavelength of the microwave with regard to the other slug.

### FIELD OF THE INVENTION

The present invention relates to a microwave introducing mechanism for introducing a microwave into a chamber in which a plasma processing is performed, a microwave plasma source using the microwave introducing mechanism, and a microwave plasma processing apparatus using the microwave plasma source.

### BACKGROUND OF THE INVENTION

In a process of manufacturing a semiconductor device or a liquid crystal display, a plasma processing apparatus such as a plasma etching apparatus and a plasma CVD film forming apparatus is employed to perform a plasma process such as an etching process or a film forming process on a target substrate to be processed such as a semiconductor wafer or a glass substrate.

A few methods for generating a plasma in the plasma processing apparatus have been disclosed. According to one of the plasma generating methods, a plasma is generated with a capacitive coupling between parallel plate electrodes arranged in a chamber while a processing gas is supplied to the chamber and a predetermined power is applied to the parallel plate electrodes. According to another plasma generating method, electrons are accelerated by an electric field formed by a microwave and a magnetic field formed by a magnetic field forming unit that is disposed outside the chamber and collide with neutral molecules in the processing gas, to thereby ionize the neutral molecules and generate a plasma.

In the case of the latter plasma generating method using the magnetron effect of the magnetic field formed by the magnetic field forming unit and the electric field formed by the microwave, a microwave having a predetermined power is supplied to an antenna disposed in the chamber through a waveguide or a coaxial tube and the microwave is radiated from the antenna to a processing space in the chamber.

A conventional and typical microwave introducing unit includes a microwave oscillator having a magnetron for outputting a microwave whose power is regulated to a predetermined level and a microwave generating power supply for supplying a DC anode current to the magnetron. The microwave introducing unit is configured to radiate the microwave to be outputted from the microwave oscillator to the processing space in the chamber through the antenna.

Since, however, the magnetron has a short lifespan of about half a year, the microwave introducing device using the magnetron has a drawback in which the cost for the equipment and the maintenance thereof is high. Further, the magnetron has oscillation stability of approximately 1% and output stability of approximately 3%, whose respective deviations are large. For that reason, it is difficult to have a stable microwave oscillation.

Accordingly, Japanese Patent Application publication No. 2004-128141 (patent document 1) has disclosed a technique for ensuring a long life of the device and stable microwave output by generating required high power microwaves by amplifying low-power microwaves through the use of amplifiers, i.e., solid state amplifiers, using semiconductor amplifying devices. This technique involves steps of dividing a microwave by a divider; amplifying the microwaves outputted from the divider by the solid state amplifiers; and combining the microwaves amplified by the solid state amplifiers by a combiner.

However, the technique in the patent document 1 is disadvantageous in that an accurate impedance matching is required in a combiner; a large-sized isolator is required to transmit to the isolator itself the high-power microwaves outputted from the combiner; and it is difficult to adjust an output distribution of the microwave in the surface of the antenna.

In order to mend such drawbacks, Japanese Patent Application publication No. 2004-128385 (patent document 2) has suggested a technique for dividing a microwave into a plurality of microwaves by a divider and amplifying the divided microwaves by amplifiers. Thereafter, the amplified microwaves are radiated from a plurality of antennas without combining the microwaves by a combiner. The radiated microwaves are combined in a space.

The technique, however, is disadvantageous in that the apparatus becomes complicated because it is required that two or more large-sized stub tuners are installed in each of the divided channels and a mismatching portion is tuned. Further, it is difficult to adjust the impedance of the mismatching portion with high accuracy.

In order to mend such drawbacks, International Patent Application publication No. WO2008/013112 (patent document 3) has disclosed a microwave plasma source which divides a microwave into a plurality of microwaves and transmits the microwaves to the chamber through a plurality of antenna modules, each of which includes a slug tuner and a slot antenna having a planar shape provided as a single unit, and an amplifier arranged to be located close to the slug tuner and the slot antenna.

By providing the antenna and the tuner as a single unit, it is possible to significantly scale down the microwave plasma source itself. Further, by providing the amplifier, the tuner and the antenna closely to each other, it is possible to tune the antenna attachment part including an impedance mismatching portion, thereby reducing the affect of the reflection reliably.

However, such technique in the patent document 3 is disadvantageous due to the following reasons. In the patent document 3, two slugs made of a dielectric material such as resin or quartz are employed as a best slug tuner and the impedance is adjusted by moving the slugs. The range of motion (ROM) of the slugs is set to be same as a ½ wavelength of the microwave and the distance between the two slugs is set to be same as the ½ wavelength to adjust the impedance in an overall range of the smith chart. Further, when the effective wavelength of the microwave is kg, the thickness of the slug becomes λg/4.

However, as necessary, it is required to increase λ and form the slugs thickly depending on the kinds of the material. Besides, since a portion of ¼ wavelength around the antenna becomes a mismatching portion, it is difficult to use the portion to adjust the impedance. Accordingly, it is necessary to obtain the length by adding the ¼ wavelength into the ROM. To that end, since the length of the main chamber in the microwave introducing mechanism including the antenna and the tuner provided as a single unit becomes increased, the scaling-down of the microwave plasma source may be restricted.

### SUMMARY OF THE INVENTION

In view of the above, the present invention provides a microwave introducing mechanism, a microwave plasma source using the same and a microwave plasma processing apparatus, capable of scaling down the microwave plasma source.

In accordance with a first aspect of the present invention, there is provided a microwave introducing mechanism used for a microwave plasma source for generating a microwave plasma in a chamber. The mechanism includes: a main body container having a cylindrical shape; an inner conductor, having a cylindrical shape or a rod shape, coaxially provided in the main body container, a microwave transmission path being defined between the main body container and the inner conductor; a tuner for adjusting an impedance of the microwave transmission path; and an antenna section including a microwave radiating antenna for radiating to the chamber a microwave transmitted through the microwave transmission path. The tuner includes a pair of slugs made of a dielectric material, the slugs being movable along the inner conductor; an actuator for moving the slugs; and a controller for controlling the movement of the slugs, and the controller controls the actuator to move both of the slugs together in a range of a ½ wavelength of the microwave while maintaining a same distance between the slugs and to move one of the slugs in a range of a ¼ wavelength of the microwave with regard to the other slug.

In the first aspect of the present invention, the slugs are preferably made of a high-purity alumina. Further, the microwave radiating antenna is preferably a planar slot antenna having slots through which a microwave is radiated.

In accordance with a second aspect of the present invention, there is provided a microwave introducing mechanism used for a microwave plasma source for generating a microwave plasma in a chamber. The mechanism includes: a main body container having a cylindrical shape; an inner conductor, having a cylindrical shape or a rod shape, coaxially provided in the main body container, a microwave transmission path being defined between the main body container and the inner conductor; a tuner for adjusting an impedance of the microwave transmission path; and an antenna section including a microwave radiating antenna for radiating to the chamber a microwave transmitted through the microwave transmission path. The microwave radiating antenna is a planar slot antenna on which four or more slots for radiating a microwave are uniformly formed, and the tuner includes a pair of slugs made of a dielectric material, the slugs being movable along the inner conductor; and an actuator for moving the slugs. Further, the slugs are made of a high-purity alumina.

In accordance with a third aspect of the present invention, there is provided a microwave introducing mechanism used for a microwave plasma source for generating a microwave plasma in a chamber. The mechanism includes: a main body container having a cylindrical shape; an inner conductor, having a cylindrical shape or a rod shape, coaxially provided in the main body container, a microwave transmission path being defined between the main body container and the inner conductor; a tuner for adjusting an impedance of the microwave transmission path; and an antenna section including a microwave radiating antenna for radiating to the chamber a microwave transmitted through the microwave transmission path. The microwave radiating antenna is a planar slot antenna on which four or more slots for radiating a microwave are uniformly formed, and the tuner includes a pair of slugs made of a dielectric material, the slugs being movable along the inner conductor; an actuator for moving the slugs; and a controller for controlling the movement of the slugs. Further, the controller controls the actuator to move both of the slugs together in a range of a ½ wavelength of the microwave while maintaining a same distance between the slugs and to move one of the slugs in a range of a ¼ wavelength of the microwave with regard to the other slug.

In accordance with a fourth aspect of the present invention, there is provided a microwave introducing mechanism used for a microwave plasma source for generating a microwave plasma in a chamber. The mechanism includes: a main body container having a cylindrical shape; an inner conductor, having a cylindrical shape or a rod shape, coaxially provided in the main body container, a microwave transmission path being defined between the main body container and the inner conductor; a tuner for adjusting an impedance of the microwave transmission path; and an antenna section including a microwave radiating antenna for radiating to the chamber a microwave transmitted through the microwave transmission path. The microwave radiating antenna is a planar slot antenna on which four or more slots for radiating a microwave are uniformly formed, and the tuner includes a pair of slugs made of a dielectric material, the slugs being movable along the inner conductor; an actuator for moving the slugs; and a controller for controlling the movement of the slugs. Further, the slugs are made of a high-purity alumina, and the controller controls the actuator to move both of the slugs together in a range of a ½ wavelength of the microwave while maintaining a same distance between the slugs and to move one of the slugs in a range of a ¼ wavelength of the microwave with regard to the other slug.

In the first to fourth aspect of the present invention, the slots preferably have a fan shape. Moreover, the antenna section preferably includes a ceiling plate made of a dielectric material through which the microwave radiated from the antenna passes; and a wave retardation member provided on an opposite side of the ceiling plate and made of a dielectric material for shortening a wavelength of the microwave transmitted to the antenna. Further, the tuner and the antenna preferably constitute a lumped constant circuit, and the tuner and the antenna preferably serve as a resonator

In accordance with a fifth aspect of the present invention, there is provided a microwave plasma source which turns a gas supplied to a chamber into a plasma by introducing a microwave into the chamber. The source includes: a microwave generating mechanism for generating a microwave; and a microwave introducing mechanism for introducing the generated microwave into the chamber. The introducing mechanism includes a main body container having a cylindrical shape; an inner conductor, having a cylindrical shape or a rod shape, coaxially provided in the main body container, a microwave transmission path being defined between the main body container and the inner conductor; a tuner for adjusting an impedance of the microwave transmission path; and an antenna section including a microwave radiating antenna for radiating to the chamber a microwave transmitted through the microwave transmission path. The tuner includes a pair of slugs made of a dielectric material, the slugs being movable along the inner conductor; an actuator for moving the slugs; and a controller for controlling the movement of the slugs, and the controller controls the actuator to move both of the slugs together in a range of a ½ wavelength of the microwave while maintaining a same distance between the slugs and to move one of the slugs in a range of a ¼ wavelength of the microwave with regard to the other slug.

In accordance with a sixth aspect of the present invention, there is provided a microwave plasma source which turns a gas supplied to a chamber into a plasma by introducing a microwave into the chamber. The source includes: a microwave generating mechanism for generating a microwave; and a microwave introducing mechanism for introducing the generated microwave into the chamber. The introducing mechanism includes a main body container having a cylindrical shape; an inner conductor, having a cylindrical shape or a rod shape, coaxially provided in the main body container, a microwave transmission path being defined between the main body container and the inner conductor; a tuner for adjusting an impedance of the microwave transmission path; and an antenna section including a microwave radiating antenna for radiating to the chamber a microwave transmitted through the microwave transmission path. The microwave radiating antenna is a planar slot antenna on which four or more slots for radiating a microwave are uniformly formed, and the tuner includes a pair of slugs made of a dielectric material, the slugs being movable along the inner conductor; and an actuator for moving the slugs. Further, the slugs are made of a high-purity alumina.

In accordance with a seventh aspect of the present invention, there is provided a microwave plasma apparatus which performs a process on a substrate by using a microwave plasma. The apparatus includes: a chamber for accommodating therein a target substrate to be processed; a gas supply unit for supplying a gas into the chamber; and a microwave plasma source, including a microwave generating mechanism for generating a microwave; and a microwave introducing mechanism for introducing the generated microwave into the chamber, for turning a gas supplied to the chamber into a plasma by introducing the microwave into the chamber. The introducing mechanism includes a main body container having a cylindrical shape; an inner conductor, having a cylindrical shape or a rod shape, coaxially provided in the main body container, a microwave transmission path being defined between the main body container and the inner conductor; a tuner for adjusting an impedance of the microwave transmission path; and an antenna section including a microwave radiating antenna for radiating to the chamber a microwave transmitted through the microwave transmission path. The tuner includes a pair of slugs made of a dielectric material, the slugs being movable along the inner conductor; an actuator for moving the slugs; and a controller for controlling the movement of the slugs, and the controller controls the actuator to move both of the slugs together in a range of a ½ wavelength of the microwave while maintaining a same distance between the slugs and to move one of the slugs in a range of a ¼ wavelength of the microwave with regard to the other slug.

In accordance with an eighth aspect of the present invention, there is provided a microwave plasma apparatus which performs a process on a substrate by using a microwave plasma. The apparatus includes: a chamber for accommodating therein a target substrate to be processed; a gas supply unit for supplying a gas into the chamber; and a microwave plasma source, including a microwave generating mechanism for generating a microwave; and a microwave introducing mechanism for introducing the generated microwave into the chamber, for turning a gas supplied to the chamber into a plasma by introducing the microwave into the chamber, wherein the introducing mechanism includes a main body container having a cylindrical shape; an inner conductor, having a cylindrical shape or a rod shape, coaxially provided in the main body container, a microwave transmission path being defined between the main body container and the inner conductor; a tuner for adjusting an impedance of the microwave transmission path; and an antenna section including a microwave radiating antenna for radiating to the chamber a microwave transmitted through the microwave transmission path. The microwave radiating antenna is a planar slot antenna on which four or more slots for radiating a microwave are uniformly formed, and the tuner includes a pair of slugs made of a dielectric material, the slugs being movable along the inner conductor; and an actuator for moving the slugs. Further, the slugs are made of a high-purity alumina.

In the first aspect of the present invention, the tuner including the pair of slugs made of a dielectric material, the slugs being movable along the inner conductor and the microwave transmission path being defined between the main body container and the inner conductor; the actuator for moving the slugs; and the controller for controlling the movement of the slugs is used as a slug tuner. Moreover, the controller controls the actuator to move both of the slugs together in the range of the ½ wavelength of the microwave while maintaining the same distance between the slugs and to move one of the slugs in the range of the ¼ wavelength of the microwave with regard to the other slug. Accordingly, it is possible to shorten a moving range of the slugs by a ¼ wavelength as compared with the conventional method, thereby allowing the microwave introducing mechanism to be scaled down. This contributes to the scaling-down of the microwave plasma source.

In the second aspect of the present invention, the tuner including the pair of slugs made of a dielectric material, the slugs being movable along the inner conductor and the microwave transmission path being defined between the main body container and the inner conductor; and the actuator for moving the slugs. Moreover, the slugs are made of the high-purity alumina. Since the high-purity alumina has a high dielectric constant, the slugs can be formed to have a thinner thickness than that of a slug made of quartz or resin and, thus, it is possible to scale down the microwave introducing mechanism by the reduced size. Further, due to the high dielectric constant, it is possible to widen the load matching range. Besides, since tan δ is small, this helps to reduce the amount of loss and degree of distortion in the microwave.

In the third aspect of the present invention, similar to the first aspect, the controller controls the actuator to move both of the slugs together in the range of the ½ wavelength of the microwave while maintaining the same distance between the slugs and to move one of the slugs in the range of the ¼ wavelength of the microwave with regard to the other slug. Then, as the microwave radiating antenna, the planar slot antenna in which four or more slots are uniformly formed is used. Accordingly, it is possible to shorten the moving range of the slugs by the ¼ wavelength as compared with the conventional method and to remove a mismatching portion near to the antenna. For that reasons, it is possible to scale down the microwave introducing mechanism much further. This contributes to the scaling-down of the microwave plasma source.

In the fourth aspect of the present invention, a pair of slugs is made of the high-purity alumina; the planar slot antenna in which four or more slots are uniformly formed is used as the microwave radiating antenna; and the controller controls the actuator to move both of the slugs together in the range of the ½ wavelength of the microwave while maintaining the same distance between the slugs and to move one of the slugs in the range of the ¼ wavelength of the microwave with regard to the other slug. Accordingly, the effects of the first aspect and the second aspect are mixed and, thus, it is possible to scale down the microwave introducing mechanism much further. This contributes to the scaling-down of the microwave plasma source.

### BRIEF DESCRIPTION OF THE DRAWINGS

FIG. 1 is a cross sectional view showing a schematic configuration of a plasma processing apparatus including a microwave plasma source having a microwave introducing mechanism in accordance with an embodiment of the present invention;

FIG. 2 is a block diagram showing a configuration of the microwave plasma source shown in FIG. 1;

FIG. 3 shows an example of a circuit configuration of a main amplifier;

FIG. 4 is a cross sectional view showing the microwave introducing mechanism in the microwave plasma processing apparatus shown in FIG. 1;

FIG. 5 is a plan view showing a preferable shape of a planar slot antenna;

FIG. 6 is a perspective view showing an antenna section having a rectangular ceiling plate;

FIG. 7 shows a smith chart for explaining a range of motion of a conventional slug when the impedance is adjusted by using the conventional slug;

FIG. 8 shows the range of motion of the conventional slug when the impedance is adjusted by using the conventional slug;

FIG. 9 shows a smith chart for explaining the range of motion of a slug when the impedance is adjusted by using the slug in accordance with the present invention;

FIG. 10 shows the range of motion of the slug when the impedance is adjusted by using the slug in accordance with the present invention;

FIG. 11 shows a smith chart showing a matching range depending on the material of the slug; and

FIG. 12 shows a mismatching portion near to an antenna section in a conventional microwave inducing mechanism.

### DETAILED DESCRIPTION OF THE EMBODIMENTS

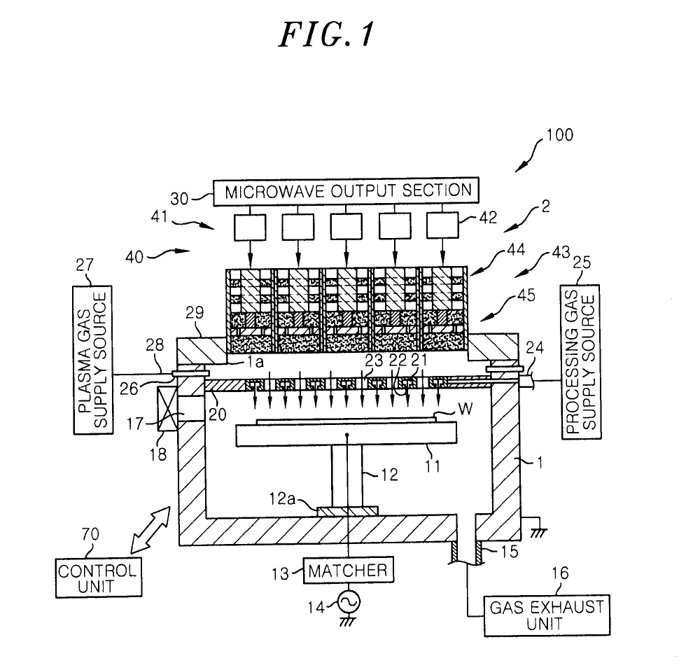

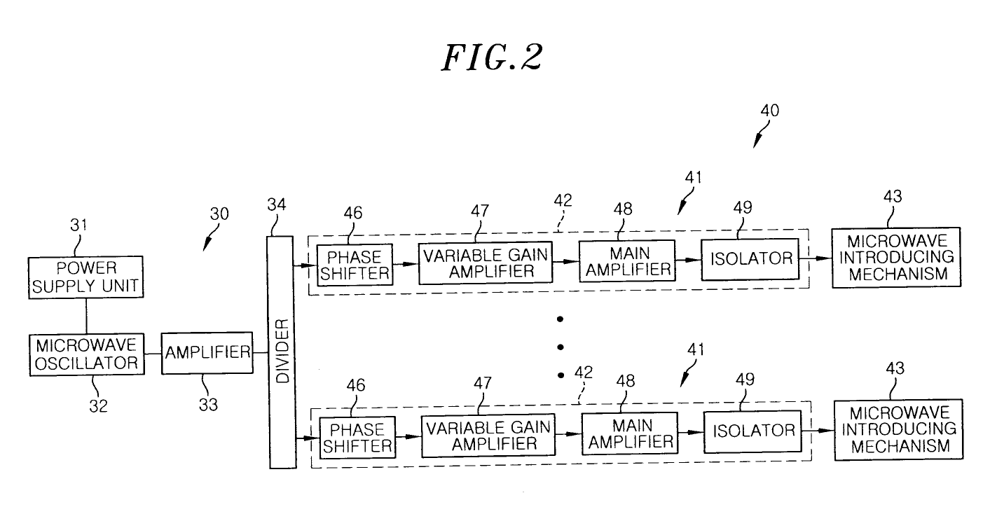

An embodiment of the present invention will now be described with reference to the accompanying drawings which form a part hereof. FIG. 1 is a cross sectional view showing a schematic configuration of a plasma processing apparatus including a microwave plasma source having a microwave introducing mechanism in accordance with an embodiment of the present invention, and FIG. 2 is a block diagram showing a configuration of the microwave plasma source shown in FIG. 1.

A plasma processing apparatus 100 is configured as a plasma etching apparatus for performing on a wafer a plasma process, e.g., an etching process. The plasma processing apparatus 100 includes a substantially cylindrical airtight chamber 1 that is grounded and made of a metal material such as aluminum, stainless steel or the like; and a microwave plasma source 2 for generating a microwave plasma in the chamber 1. An opening 1a is formed at an upper portion of the chamber 1, and the microwave plasma source 2 is provided in the opening 1a to face an inside of the chamber 1.

In the chamber 1, a susceptor 11 for horizontally supporting a wafer W as a target substrate to be processed is provided while being supported by a cylindrical supporting member 12 provided upwardly at a center of a bottom portion of the chamber 1 via an insulating member 12a. The susceptor 11 and the insulating member 12a are made of, e.g., aluminum, the surface of which is alumite-treated (anodically oxidized), or the like.

In addition, the susceptor 11 is provided with an electrostatic chuck for electrostatically attracting the wafer W; a temperature-control mechanism; a gas channel through which a heat-transfer gas is supplied to a backside of the wafer W; an elevating pin which can move up and down to transfer the wafer W, and the like, which are not shown. Further, a high frequency bias power supply 14 is electrically connected to the susceptor 11 via a matcher 13. Ions are attracted to the wafer W by a high frequency power supplied from the high frequency bias power supply 14 to the susceptor 11.

A gas exhaust line 15 is connected to a bottom portion of the chamber 1, and a gas exhaust unit 16 having a vacuum pump is connected to the gas exhaust line 15. By operating the gas exhaust unit 16, the inside of the chamber 1 is exhausted and depressurized to a predetermined vacuum level at a high speed. Further provided in a sidewall of the chamber 1 are a loading/unloading port 17 through which the wafer W is loaded and unloaded; and a gate valve for opening and closing the loading/unloading port 17.

A shower plate 20 through which a processing gas for plasma etching is injected toward the wafer W is horizontally provided above the susceptor 11 in the chamber 1. The shower plate 20 includes grid-shaped gas channels 21 and a plurality of gas injection holes 22 formed in the gas channels 21. Respective spaces 23 are formed between the grid-shaped gas channels 21. A line 24 extending to the outside of the chamber 1 is connected to the gas channels 21, and a process gas supply source 25 is connected to the line 24.

In the meantime, a ring-shaped plasma gas introducing member 26 is provided along a chamber wall above the shower plate 20 of the chamber 1, and a plurality of gas injection holes are formed on an inner periphery of the plasma gas introducing member 26. A plasma gas supply source 27 is connected to the plasma gas introducing member 26 via a line 28. As for a plasma gas, it is preferable to use a rare gas such as Ar gas or the like.

The plasma gas introduced through the plasma gas introducing member 26 into the chamber 1 is turned into a plasma by a microwave supplied from the microwave plasma source 2. Thus generated plasma of, e.g., Ar gas, passes through the spaces 23 of the shower plate 20, so that the processing gas injected through the gas injection holes 22 of the shower plate 20 is excited, thereby generating a plasma of the processing gas.

The microwave plasma source 2 is supported by a supporting ring 29 provided at an upper portion of the chamber 1, and the gap therebetween is airtightly sealed. As shown in FIG. 2, the microwave plasma source 2 includes a microwave output section 30 for dividing a microwave into microwaves and outputting the divided microwaves through a plurality of paths; and an antenna unit 40 for guiding the outputted microwaves into the chamber 1 and radiating the guided microwaves into the chamber 1.

The microwave output section 30 includes a power supply unit 31; a microwave oscillator 32; an amplifier 33 for amplifying an oscillated microwave; and a divider 34 for dividing the amplified microwave into a plurality of microwaves.

The microwave oscillator 32 performs a phase locked loop (PLL) oscillation, for example, to generate a microwave of a predetermined frequency (e.g., 2.45 GHz). The divider 34 divides the microwave amplified by the amplifier 33 while matching the impedance between an input side and an output side to minimize the loss of the microwaves. In addition, the frequency of 8.35, 5.8, 1.98 GHz or the like may be used instead of 2.45 GHz as for the frequency of the microwaves.

The antenna unit 40 includes a plurality of antenna modules 41 for guiding the microwaves divided by the divider 34. Each of the antenna modules 41 includes an amplifier section 42 for mainly amplifying the divided microwaves; and a microwave introducing mechanism 43. The microwave introducing mechanism 43 includes a tuner 44 for matching the impedance; an antenna section 45 for radiating the amplified microwaves into the chamber 1. The microwaves radiated into the chamber 1 from the antenna section 45 of the microwave introducing mechanism 43 are combined in the space of the chamber 1.

The amplifier section 42 includes a phase shifter 46; a variable gain amplifier 47; a main amplifier 48 serving as a solid state amplifier; and an isolator 49.

The phase shifter 46 is configured to shift phases of the microwaves by a slug tuner, and it is possible to modulate the radiation characteristics by controlling the phase shifter 46. For example, it is possible to adjust the directivity by controlling the phase in each of the antenna modules, to thereby change the plasma distribution. Moreover, it is possible to obtain circular polarized waves by shifting the phase by 90° between adjacent antenna modules to be described later. However, the phase shifter 46 need not be provided when it is not necessary to modulate the radiation characteristics.

The variable gain amplifier 47 is an amplifier for controlling plasma intensity or deviation in each of the antenna modules by adjusting power levels of microwaves inputted into the maim amplifier 48. The distribution of the generated plasma can be variably controlled by changing the variable gain amplifier 47 for each of the antenna modules.

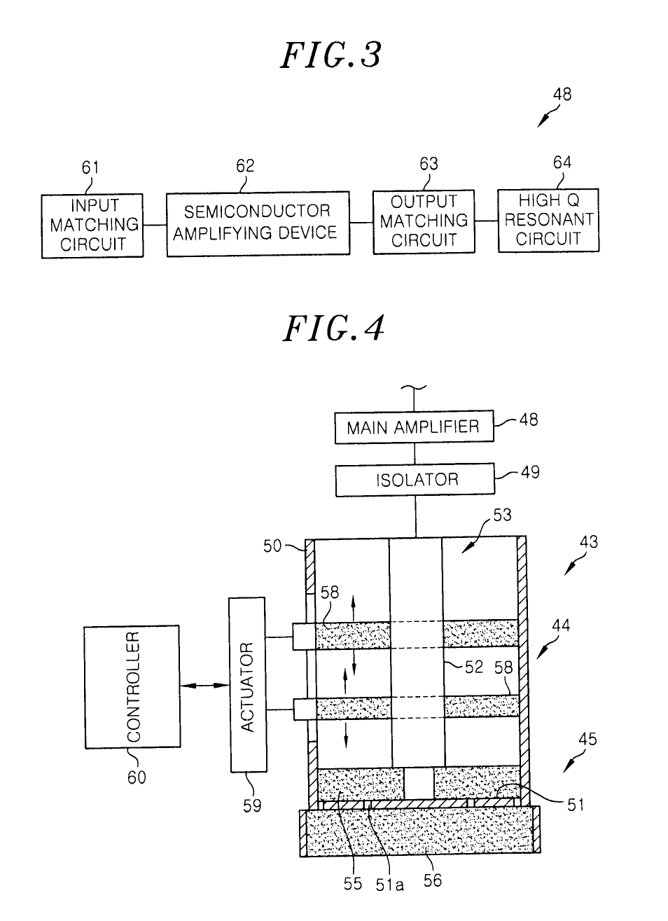

The main amplifier 48 serving as a solid state amplifier may include an input matching circuit 61; a semiconductor amplifying device 62; an output matching circuit 63; and a high Q resonant circuit as shown in FIG. 3, for example. As for the semiconductor amplifying device 62, it is possible to use GaAs high electron mobility transistor (HEMT), GaN HEMT, laterally diffused (LD)-metal oxide semiconductor (MOS) or the like, capable of performing a class E operation. Especially, when GaN HEMT is used as the semiconductor amplifying device, the variable gain amplifier has a uniform value, and the power is controlled by varying the power voltage of the amplifier for performing a class E operation.

The isolator 49 separates microwaves reflected from the antenna section 45 to main amplifier 48. The isolator includes a circulator and a dummy load (coaxial terminator). The circulator transfers to the dummy load the microwave reflected from the antenna section 45, and the dummy load converts the reflected microwave transferred from the circulator into heat.

In the present embodiment, there is provided a plurality of antenna modules 41, and the microwaves introduced into the chamber 1 from the microwave introducing mechanism 43 of each of the antenna modules 41 are combined in the space. Accordingly, the isolator 49 is preferably small sized, and can be arranged to be located adjacent to the main amplifier 48.

Next, the microwave introducing mechanism 43 will be described in detail with reference to FIG. 4. As shown in FIG. 4, the microwave introducing mechanism 43 includes a main body container 50. The antenna section 45 is arranged at an upper portion of the main body container 50, and a base end portion of the main body container 50, below the antenna section 45, serves as a portion in which the impedance can be adjusted by a tuner 44.

The main body container 50, which is cylindrical and made of a metal material, constitutes an outer conductor of the coaxial waveguide. Further, in the main body container 50, an inner conductor 52 of the coaxial tube extends upward vertically. The inner conductor 52 has a rod shape or a cylindrical shape. A microwave transmission path 53 is defined between the main body container 50 and the inner conductor 52.

The antenna section 45 includes a planar slot antenna 51 having a planar shape, and the planar slot antenna 51 has slots 51a. The inner conductor 52 is connected to a central portion of the planar slot antenna 51.

A power supply conversion unit (not shown) is installed at a base side of the main body container 50 and is connected to the main amplifier 48 via a coaxial cable. The isolator 49 is provided in the middle of the coaxial cable. The main amplifier 48 is a power amplifier dealing with a high power and thus performs a high-efficiency operation of the class E. Since, however, the heat therefrom ranges from several tens to several hundreds of watts, the main amplifier 48 is installed in series to the antenna section 45 in view of heat radiation.

The antenna section 45 includes a wave retardation member 55 provided on a top surface of the planar slot antenna 51. The wave retardation member 55 has a dielectric constant greater than that of vacuum and is made of, e.g., quartz, ceramic, polyimide-based resin or fluorine-based resin polytetrafluoroethylene or the like. The wave retardation member 55 has a function of shortening the wavelength of the microwave as compared with that in the vacuum, to thereby control the plasma. The wave retardation member 55 can adjust the phases of the microwaves depending on its thickness, and its thickness is adjusted such that an antinode of the standing wave is formed at the planar slot antenna 51. Accordingly, it is possible to maximize the radiation energy of the planar slot antenna 51 while minimizing the reflection.

Further, a dielectric member for vacuum sealing, e.g., a ceiling plate 56 made of quartz, ceramic or the like, is arranged on a bottom surface of the planar slot antenna 51. The microwaves amplified by the main amplifier 48 pass through the space between the inner conductor 52 and a surrounding wall of the main body container 50 are transmitted through the slots 51a of the planar slot antenna 51. Then, the transmitted microwaves are radiated into the chamber through the ceiling plate 56.

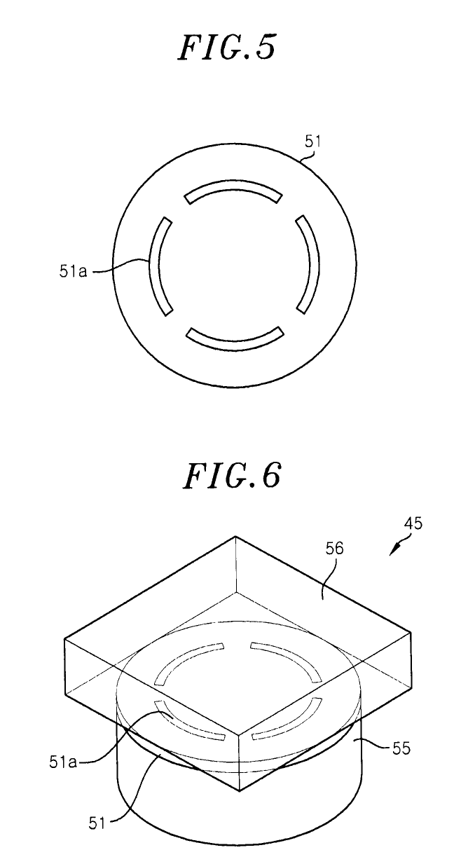

In the present embodiment, as shown in FIG. 5, four slots 51a are evenly formed in a separated arc-shape. Accordingly, since the slots 51a are substantially uniformly formed in a circumferential direction, the propagated microwaves can be suppressed from being reflected in the planar slot antenna 51, thereby reducing or substantially removing the mismatching portion as will be described later.

The slots 51a preferably have a fan shape to shorten the length of the slots 51a or allowing the slots 51a to be scaled down. Further, as shown in FIG. 6, the ceiling plate 56 preferably has a rectangular parallelepiped shape or a cylindrical shape whose diameter is greater than that of the main body container 50. Accordingly, it is possible to effectively radiate the microwaves in a TE mode.

As shown FIG. 4, the tuner 44 includes the two slugs 48 at the base end portion of the main body container 50, below the antenna section 45 to constitute a slug tuner. The slugs 58 are made of a dielectric material and have a plate shape. Moreover, the slugs 58 are disposed in a ring shape between the inner conductor 52 and an outer wall of the main body container 50. The impedance is adjusted by vertically moving the slugs 58 by an actuator 59 based on a command from a controller 60. The controller 60 adjusts the impedance of termination to become, e.g., about 50Ω. When only one of the two slugs 58 is moved, a circular trajectory passing through the origin of the smith chart is drawn. On the other hand, when both of the slugs 58 are moved together, only the phase of the reflection coefficient is rotated.

In the present embodiment, as will be described later, the operations of the slugs 58 are controlled by an algorithm of the controller 60 and, thus, the impedance can be adjusted in all ranges by setting the range of a pair of slugs moved together same as λ/2 and the range of the slugs, one of which is fixed and the other slug is moved, same as λ/4 in case that the in-line wavelength (wavelength in waveguide) is set to be same as λ. Accordingly, as will be described later, the total moving range of the two slugs 58 can be determined to be 3λ/4, which is smaller than that of the conventional slugs.

In the present embodiment, the slugs 58 are made of a dielectric material, e.g., high-purity alumina. The high-purity alumina has a relative dielectric constant of 10, which is significantly greater than 3.88 of quartz and 2.03 of Teflon (registered trademark). Accordingly, it is possible to enlarge the matching range by making alumina thinner. Further, the high-purity alumina is advantageous in having small tan δ, reducing loss and suppressing distortion as compared with quartz and Teflon (registered trademark). The high-purity alumina also has a high heat resistance. Preferably, an alumina sintered body of the purity of 99.9% or more is employed as the high-purity alumina. As a specific product name, a SAPPHAL made by the Covalent Materials Corp. may be exemplified. A single-crystal alumina (sapphire) may be employed.

In the present embodiment, the main amplifier 48, the tuner 44 and the planar slot antenna 51 are arranged to be located close to one another. Further, the tuner 44 and the planar slot antenna 51 are included in a lumped constant circuit within ½ wavelength and also serve as a resonator.

Each unit of the plasma processing apparatus 100 is controlled by a control unit 70 having a micro processor. The control unit 70 includes a storage unit which stores process recipes, an input unit, a display unit and the like and controls the plasma processing apparatus based on a selected recipe.

Next, an operation of the plasma processing apparatus having such configuration will be described. First, the wafer W is loaded into the chamber 1 and is mounted on the susceptor 11. Then, while a processing gas, e.g., Ar gas, is introduced from the plasma gas supply source 27 into the chamber 1 via a line 28 and the plasma gas introducing member 26, a microwave is introduced from the microwave plasma source 2 into the chamber 1, thereby generating a plasma.

Thereafter, a processing gas, e.g., an etching gas such as Cl₂ gas or the like, is injected from the processing gas supply source 25 into the chamber 1 via the line 24 and the shower plate 20. The injected processing gas is excited by the plasma that has passed through the spaces 23 of the shower plate 20, to thereby be turned into a plasma. The plasma of the processing gas thus generated is used to perform a plasma process, e.g., an etching process, on the wafer W.

In this case, in the microwave plasma source 2, the microwave oscillated by the microwave oscillator 32 of the microwave output section 30 is amplified by the amplifier 33 and is then divided into a plurality of microwaves by the divider 34, and the divided microwaves are guided to antenna modules 41 of the antenna unit 40. In the antenna modules 41, the divided microwaves are individually amplified by the main amplifier 48 serving as the solid state amplifier and pass through the microwave transmission path 53. Then, the microwaves are individually radiated from the planar slot antenna 51 and introduced into the chamber 1. Thereafter, the introduced microwaves are combined in a space. Accordingly, it becomes unnecessary to use the large-scaled isolator or combiner. In addition, the microwave introducing mechanism 43 is provided compactly since the antenna section 45 and the tuner 44 are provided as a single unit. Further, the main amplifier 48, the tuner 44 and the planar slot antenna 51 are arranged to be installed close to one another. Especially, the tuner 43 and the planar slot antenna 51 are included in a lumped constant circuit and also serve as a resonator. Accordingly, in a planar slot antenna installation portion where the impedance mismatching exists, the tuning can be performed with high accuracy by the tuner 43, thereby reliably solving the effects of reflection.

Moreover, since the tuner 44 and the planar slot antenna 51 are arranged to be located close to each other and are included in the lumped constant circuit and also serve as the resonator as described above, this makes impedance mismatching up to the planar slot antenna 51 eliminated accurately, thereby allowing the mismatching portion to substantially serve as the plasma space. Accordingly, the plasma control can be performed with high accuracy by the tuner 44. Further, it is possible to efficiently radiate the microwaves as TE waves by forming in a quadrangular or cylindrical shape the ceiling plate 56 attached to the planar slot antenna 51.

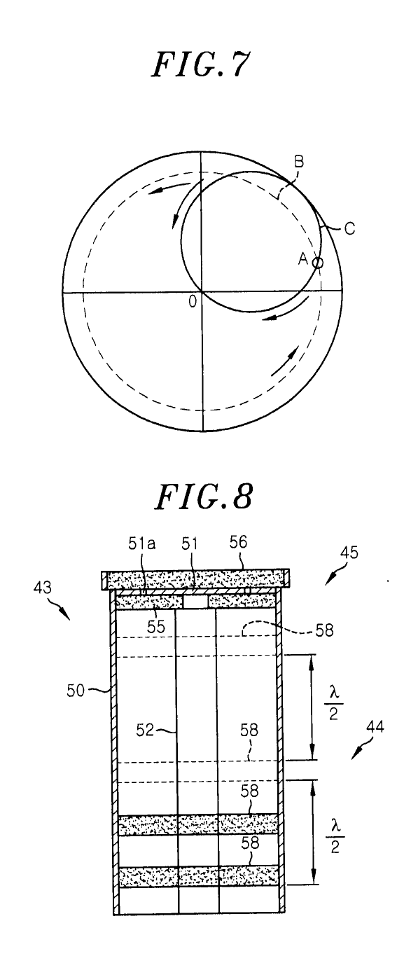

However, since the microwave introducing mechanism 43 adjusts the impedance by moving the slugs 58 of the tuner 44, it is required to obtain the length corresponding to the moving margin of the slugs 58. In the conventional method, in case that the in-line wavelength of the microwave is set as λ, it is possible to shift by 360° the phase of the reflection coefficient of a point A on the smith chart, for example, as shown in FIG. 7 (the dotted-line trajectory of a circle B) by moving both of the slugs 58 together in the range of λ/2; and to draw a circle C which passes through the origin and a point A by moving only one of the slugs 58 in range of λ/2 with regard to the other slug. Accordingly, it is possible to adjust the impedance at all points by using the combinations thereof. Therefore, as shown in FIG. 8, the range of motion (ROM) of the slugs 58 becomes λ by adding λ/2 to λ/2.

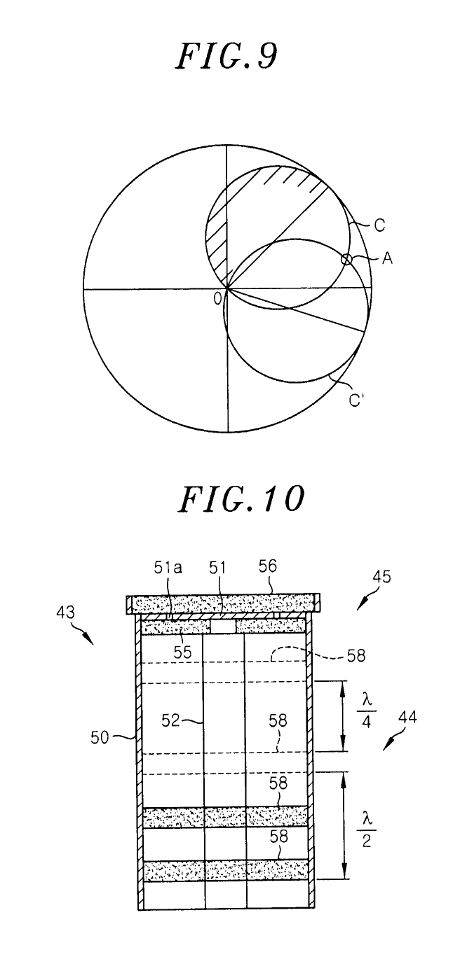

On the other hand, in the present embodiment, the ROM of one of the slugs 58 with regard to the other slug is set to λ/4, which is a half of the range of the conventional method. Specifically, the ROM on the circle C shown in FIG. 7 is converted into a ROM represented by a shaded area shown in FIG. 9, for example. In this case, since the point A is located beyond the ROM of the circle C, the controller 60, for example, selects a circle C′ as the circle that passes through the origin and the point A. In this way, the point A can be moved to the origin along the ROM of the circle C′, thereby adjusting the impedance in the ROM of λ/4. Accordingly, as shown in FIG. 10, the ROM of the slugs 58 becomes 3λ/4 by adding λ/2 and λ/4, which is shorter by λ/4 than that of the conventional method. Therefore, it is possible to shorten the length of the main body container 50 of the microwave introducing mechanism 43 by λ/4, to thereby allowing the microwave plasma source 2 to be scaled down more and more.

Moreover, in the present embodiment, since a high-purity alumina having a high dielectric constant is employed as a dielectric material which the slugs 58 are made of, it is possible to make the slugs 58 thinner. Specifically, a thickness d of the slugs 58 is calculated by using an equation, d=λg/4, where λg indicates an equivalent wavelength of the microwave (the wavelength of the microwave in the slugs 58). However, when the wavelength of the microwave in the air is referred to as λ and the relative dielectric constant is referred to as ∈ᵣ, it is possible to obtain an equation λg=λ/∈ᵣ^{1/2}.

Accordingly, the thickness of the slugs 58 can be made thinner as the relative dielectric constant becomes higher. Since the high-purity alumina has a relative dielectric constant of 10, which is significantly greater than 3.88 of quartz and 2.03 of Teflon (registered trademark), it is possible to make the slugs 58 thinner, i.e., with an about ⅔ thickness of the conventional slug made of quartz. To be specific, as compared with the thickness of 16 mm of the slug made of quartz, the slug 58 made of alumina can have the thickness of 10 mm. For that reason, it is possible to shorten the length of the main body container 50 of the microwave introducing mechanism 43 into 12 mm resultantly, thereby allowing the microwave plasma source 2 to be scaled down by the shortened length.

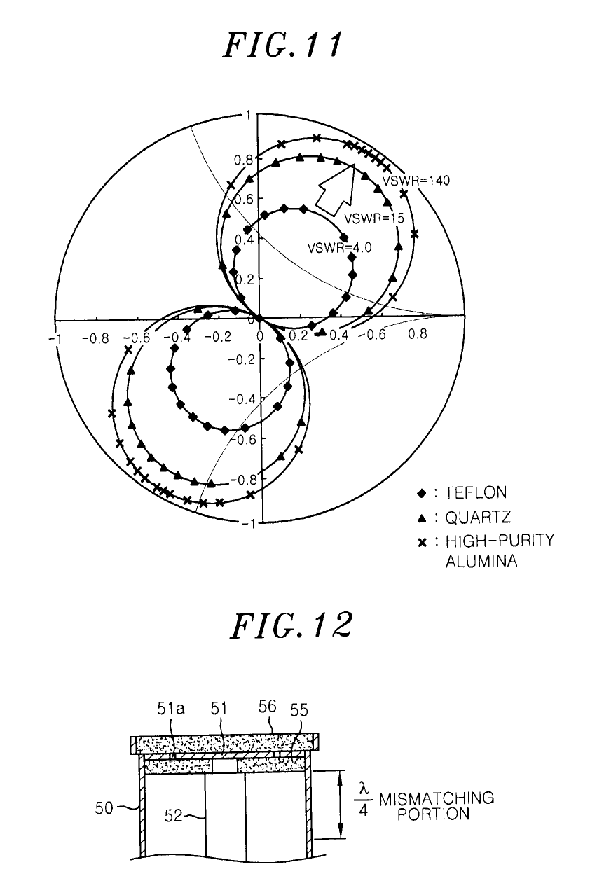

Moreover, it is possible to widen the matching range by using a material having a high dielectric constant. FIG. 11 is the smith chart showing a load matching range in the case of using a slug of each material calculated by employing the calculating method for a distributed constant circuit. In the case of using the high-purity alumina, it is possible to increase the load matching range, thereby widening the adjustment margin, as compared with the case of using quartz or Teflon (registered trademark).

Since an increase in the dielectric constant of the slugs 58 leads to an increase in an attenuation constant, the loss may also be increased. However, the thickness itself of the slug can be reduced, thereby balancing the loss. Moreover, since the high-purity alumina has small tan δ, the loss can be reduced more efficiently as compared with the case of using quartz or Teflon (registered trademark). Specifically, in the case of using the conventional slug made of quartz, the voltage standing wave radio (VSWR) has about 20 at the maximum. On the contrary, in the case of using the slug made of the high-purity alumina, the VSWR can be increased to about 70.

Since the high-purity alumina has a high resistance compared with quartz or Teflon (registered trademark), the deformation does not occur even at the high temperature of 1500° C.

Besides, in the present embodiment, the four slots 51a of the slot antenna 51 are uniformly formed and, thus, it is possible to more uniformly radiate the microwave. As a result, it is possible to reduce or remove the mismatching portion near to the antenna section 45.

Specifically, in the case of providing two slots, the radiation uniformity of the microwaves from the planar slot antenna 51 is not necessarily high and, thus, a λ/4 area near to the antenna section 45 of the main body container 50 becomes a mismatching portion as shown in FIG. 12. Accordingly, the mismatching portion has not been used for adjusting the impedance by the slugs 58. However, the mismatching portion can be reduced or removed by uniformly forming the four slots and, thus, the λ/4 area can be used to adjust the impedance by the slugs 58. Therefore, it is possible to shorten the length of the main body container 50 of the microwave introducing mechanism 43 by λ/4 at the maximum, thereby allowing the microwave plasma source to be scaled down by the shortened length.

As such, it is possible to shorten the length of the main body container 50 of the microwave introducing mechanism 43 by controlling the movement of the slugs 58. By using the high-purity alumina as the material of the slugs 58, it is also possible to shorten the length of the main body container 50 by about 12 mm as compared with the case of using the conventional slug made of quartz. Further, by uniformly providing four slots 51a of the planar slot antenna 51, it is possible to shorten the length of the main body container 50 by λ/4.

Accordingly, by only one of the above methods, it is possible to allow the microwave plasma source 2 to be scaled down. Further, by the synergy effect by using a combination of the above methods, it is possible to allow the microwave plasma source 2 to be scaled down much further. Especially, by combining the three methods, since λ becomes about 12.2 cm, it is possible to shorten the length of the main body container 50 by about 7.3 cm at the maximum.

The present invention is not limited to the above embodiments, and can be variously modified within the scope of the present invention. For example, the circuit configurations of the microwave output section 30, the antenna unit 40, the main amplifier 47 and the like are not limited to those described in the above embodiments. To be specific, the phase shifter becomes unnecessary when there is no need to control the directivity of the microwave radiated from the planar slot antenna or to obtain the circular polarized waves. Moreover, the antenna unit 40 is not necessarily provided with a plurality of antenna modules 41, and a single antenna module is sufficient in a small-sized plasma source such as a remote plasma or the like.

In the present embodiment, all the shortenings in the length of the main body container 50 are performed by employing three methods of controlling the movement of the slugs 58 by the controller 60; using the high-purity alumina as the material of slugs 58; and uniformly forming four slots of the planar slot antenna 51. Alternatively, any one or two of the methods may be used. In this case, the remaining conditions may be set to be identical to that of the conventional method.

Although the four slots 51a of the antenna 51 is uniformly formed in the present embodiment, five or more slots may be formed; or one to three slots may be formed with a little reduced efficiency. The slot(s) formed in the planar slot antenna 51 preferably has a fan shape so as to be scaled down by shortening the length thereof, but is not limited thereto.

Further, although an etching processing apparatus is used as an example of a plasma processing apparatus in the above embodiments, it is not limited thereto. Other plasma processing apparatuses for performing a film forming process, an oxynitride film forming process, an ashing process and the like may be used. Furthermore, the target substrate to be processed is not limited to the semiconductor wafer W. Alternatively, the target substrate may be one of various substrates, which are used in a flat panel display (FPD) including a liquid crystal display (LCD) as a representative example, a ceramic substrate or the like.

While the invention has been shown and described with respect to the embodiments, it will be understood by those skilled in the art that various changes and modifications may be made without departing from the scope of the invention as defined in the following claims.

What is claimed is:

1. A microwave introducing mechanism used for a microwave plasma source for generating a microwave plasma in a chamber, the mechanism comprising:
a main body container having a cylindrical shape;
an inner conductor, having a cylindrical shape or a rod shape, coaxially provided in the main body container, a microwave transmission path being defined between the main body container and the inner conductor;
a tuner for adjusting an impedance of the microwave transmission path; and
an antenna section including a microwave radiating antenna for radiating to the chamber a microwave transmitted through the microwave transmission path,
wherein the tuner includes a pair of slugs made of a dielectric material, the slugs being movable along the inner conductor; an actuator for moving the slugs; and a controller for controlling the movement of the slugs, and
the controller controls the actuator to move both of the slugs together in a range of a ½ wavelength of the microwave while maintaining a same distance between the slugs and to move one of the slugs in a range of a ¼ wavelength of the microwave with regard to the other slug.

2. The microwave introducing mechanism of claim 1, wherein the slugs are made of a high-purity alumina.

3. The microwave introducing mechanism of claim 1, wherein the microwave radiating antenna is a planar slot antenna having slots through which a microwave is radiated.

4. The microwave introducing mechanism of claim 3, wherein the slots have a fan shape.

5. The microwave introducing mechanism of claim 1, wherein the antenna section includes a ceiling plate made of a dielectric material through which the microwave radiated from the antenna passes; and a wave retardation member provided on an opposite side of the ceiling plate and made of a dielectric material for shortening a wavelength of the microwave transmitted to the antenna.

6. The microwave introducing mechanism of claim 1, wherein the tuner and the antenna constitute a lumped constant circuit.

7. The microwave introducing mechanism of claim 1, wherein the tuner and the antenna serve as a resonator.

8. A microwave introducing mechanism used for a microwave plasma source for generating a microwave plasma in a chamber, the mechanism comprising:
a main body container having a cylindrical shape;
an inner conductor, having a cylindrical shape or a rod shape, coaxially provided in the main body container, a microwave transmission path being defined between the main body container and the inner conductor;
a tuner for adjusting an impedance of the microwave transmission path; and
an antenna section including a microwave radiating antenna for radiating to the chamber a microwave transmitted through the microwave transmission path,
wherein the microwave radiating antenna is a planar slot antenna on which four or more slots for radiating a microwave are uniformly formed,
the tuner includes a pair of slugs made of a dielectric material, the slugs being movable along the inner conductor; and an actuator for moving the slugs, and
the slugs are made of a high-purity alumina.

9. The microwave introducing mechanism of claim 8, wherein the slots have a fan shape.

10. The microwave introducing mechanism of claim 8, wherein the antenna section includes a ceiling plate made of a dielectric material through which the microwave radiated from the antenna passes; and a wave retardation member provided on an opposite side of the ceiling plate and made of a dielectric material for shortening a wavelength of the microwave transmitted to the antenna.

11. The microwave introducing mechanism of claim 8, wherein the tuner and the antenna constitute a lumped constant circuit.

12. The microwave introducing mechanism of claim 8, wherein the tuner and the antenna serve as a resonator.

13. A microwave introducing mechanism used for a microwave plasma source for generating a microwave plasma in a chamber, the mechanism comprising:
a main body container having a cylindrical shape;
an inner conductor, having a cylindrical shape or a rod shape, coaxially provided in the main body container, a microwave transmission path being defined between the main body container and the inner conductor;
a tuner for adjusting an impedance of the microwave transmission path; and
an antenna section including a microwave radiating antenna for radiating to the chamber a microwave transmitted through the microwave transmission path,
wherein the microwave radiating antenna is a planar slot antenna on which four or more slots for radiating a microwave are uniformly formed,
the tuner includes a pair of slugs made of a dielectric material, the slugs being movable along the inner conductor; an actuator for moving the slugs; and a controller for controlling the movement of the slugs, and
the controller controls the actuator to move both of the slugs together in a range of a ½ wavelength of the microwave while maintaining a same distance between the slugs and to move one of the slugs in a range of a ¼ wavelength of the microwave with regard to the other slug.

14. The microwave introducing mechanism of claim 13, wherein the slots have a fan shape.

15. The microwave introducing mechanism of claim 13, wherein the antenna section includes a ceiling plate made of a dielectric material through which the microwave radiated from the antenna passes; and a wave retardation member provided on an opposite side of the ceiling plate and made of a dielectric material for shortening a wavelength of the microwave transmitted to the antenna.

16. The microwave introducing mechanism of claim 13, wherein the tuner and the antenna constitute a lumped constant circuit.

17. The microwave introducing mechanism of claim 13, wherein the tuner and the antenna serve as a resonator.

18. A microwave introducing mechanism used for a microwave plasma source for generating a microwave plasma in a chamber, the mechanism comprising:
a main body container having a cylindrical shape;
an inner conductor, having a cylindrical shape or a rod shape, coaxially provided in the main body container, a microwave transmission path being defined between the main body container and the inner conductor;
a tuner for adjusting an impedance of the microwave transmission path; and
an antenna section including a microwave radiating antenna for radiating to the chamber a microwave transmitted through the microwave transmission path,
wherein the microwave radiating antenna is a planar slot antenna on which four or more slots for radiating a microwave are uniformly formed,
the tuner includes a pair of slugs made of a dielectric material, the slugs being movable along the inner conductor; an actuator for moving the slugs; and a controller for controlling the movement of the slugs,
the slugs are made of a high-purity alumina, and
the controller controls the actuator to move both of the slugs together in a range of a ½ wavelength of the microwave while maintaining a same distance between the slugs and to move one of the slugs in a range of a ¼ wavelength of the microwave with regard to the other slug.

19. The microwave introducing mechanism of claim 18, wherein the slots have a fan shape.

20. The microwave introducing mechanism of claim 18, wherein the antenna section includes a ceiling plate made of a dielectric material through which the microwave radiated from the antenna passes; and a wave retardation member provided on an opposite side of the ceiling plate and made of a dielectric material for shortening a wavelength of the microwave transmitted to the antenna.

21. The microwave introducing mechanism of claim 18, wherein the tuner and the antenna constitute a lumped constant circuit.

22. The microwave introducing mechanism of claim 18, wherein the tuner and the antenna serve as a resonator.

23. A microwave plasma source which turns a gas supplied to a chamber into a plasma by introducing a microwave into the chamber, the source comprising:
a microwave generating mechanism for generating a microwave; and
a microwave introducing mechanism for introducing the generated microwave into the chamber,
wherein the introducing mechanism includes a main body container having a cylindrical shape;
an inner conductor, having a cylindrical shape or a rod shape, coaxially provided in the main body container, a microwave transmission path being defined between the main body container and the inner conductor;
a tuner for adjusting an impedance of the microwave transmission path; and
an antenna section including a microwave radiating antenna for radiating to the chamber a microwave transmitted through the microwave transmission path,
wherein the tuner includes a pair of slugs made of a dielectric material, the slugs being movable along the inner conductor; an actuator for moving the slugs; and a controller for controlling the movement of the slugs, and
the controller controls the actuator to move both of the slugs together in a range of a ½ wavelength of the microwave while maintaining a same distance between the slugs and to move one of the slugs in a range of a ¼ wavelength of the microwave with regard to the other slug.

24. A microwave plasma source which turns a gas supplied to a chamber into a plasma by introducing a microwave into the chamber, the source comprising:
a microwave generating mechanism for generating a microwave; and
a microwave introducing mechanism for introducing the generated microwave into the chamber,
wherein the introducing mechanism includes a main body container having a cylindrical shape;
an inner conductor, having a cylindrical shape or a rod shape, coaxially provided in the main body container, a microwave transmission path being defined between the main body container and the inner conductor;
a tuner for adjusting an impedance of the microwave transmission path; and
an antenna section including a microwave radiating antenna for radiating to the chamber a microwave transmitted through the microwave transmission path,
wherein the microwave radiating antenna is a planar slot antenna on which four or more slots for radiating a microwave are uniformly formed,
the tuner includes a pair of slugs made of a dielectric material, the slugs being movable along the inner conductor; and an actuator for moving the slugs, and
the slugs are made of a high-purity alumina.

25. A microwave plasma apparatus which performs a process on a substrate by using a microwave plasma, the apparatus comprising:
a chamber for accommodating therein a target substrate to be processed;
a gas supply unit for supplying a gas into the chamber; and
a microwave plasma source, including a microwave generating mechanism for generating a microwave; and a microwave introducing mechanism for introducing the generated microwave into the chamber, for turning a gas supplied to the chamber into a plasma by introducing the microwave into the chamber,
wherein the introducing mechanism includes a main body container having a cylindrical shape;
an inner conductor, having a cylindrical shape or a rod shape, coaxially provided in the main body container, a microwave transmission path being defined between the main body container and the inner conductor;
a tuner for adjusting an impedance of the microwave transmission path; and
an antenna section including a microwave radiating antenna for radiating to the chamber a microwave transmitted through the microwave transmission path,
wherein the tuner includes a pair of slugs made of a dielectric material, the slugs being movable along the inner conductor; an actuator for moving the slugs; and a controller for controlling the movement of the slugs, and
the controller controls the actuator to move both of the slugs together in a range of a ½ wavelength of the microwave while maintaining a same distance between the slugs and to move one of the slugs in a range of a ¼ wavelength of the microwave with regard to the other slug.

26. A microwave plasma apparatus which performs a process on a substrate by using a microwave plasma, the apparatus comprising:
a chamber for accommodating therein a target substrate to be processed;
a gas supply unit for supplying a gas into the chamber; and
a microwave plasma source, including a microwave generating mechanism for generating a microwave; and a microwave introducing mechanism for introducing the generated microwave into the chamber, for turning a gas supplied to the chamber into a plasma by introducing the microwave into the chamber,
wherein the introducing mechanism includes a main body container having a cylindrical shape;
an inner conductor, having a cylindrical shape or a rod shape, coaxially provided in the main body container, a microwave transmission path being defined between the main body container and the inner conductor;
a tuner for adjusting an impedance of the microwave transmission path; and
an antenna section including a microwave radiating antenna for radiating to the chamber a microwave transmitted through the microwave transmission path,
wherein the microwave radiating antenna is a planar slot antenna on which four or more slots for radiating a microwave are uniformly formed,
the tuner includes a pair of slugs made of a dielectric material, the slugs being movable along the inner conductor; and an actuator for moving the slugs, and
the slugs are made of a high-purity alumina.
